(19) United States
(12) Patent Application Publication
(10) Pub. No.: US 2025/0241101 A1
(43) Pub. Date: Jul. 24, 2025

(54) ELECTRONIC DEVICE

(71) Applicant: InnoLux Corporation, Miao-Li County (TW)

(72) Inventors: Cheng-Hsiao LIN, Miao-Li County (TW); Chia-Hao Tsai, Miao-Li County (TW); Chih-Lung Lin, Miao-Li County (TW); Mei-Wen Jao, Miao-Li County (TW)

(73) Assignee: InnoLux Corporation, Miao-Li County (TW)

(21) Appl. No.: 18/988,824

(22) Filed: Dec. 19, 2024

(30) Foreign Application Priority Data
Jan. 23, 2024 (CN) 202410091161.X

(51) Int. Cl. H10H 29/30; H10H 29/37; H10K 59/122; H10K 59/35

(52) U.S. Cl. CPC H10H 29/352; H10H 29/37; H10K 59/122; H10K 59/353

(57) ABSTRACT

An electronic device includes a substrate, a pixel defining layer disposed on the substrate and at least three light-emitting units respectively disposed in a first opening, a second opening and a third opening of the pixel defining layer. The first opening and the second opening are arranged along a first direction, and the first opening and the third opening are arranged along a second direction. An included angle between an extending direction of a first long axis of the first opening and the first direction is greater than 45 degrees, an included angle between the extending direction of the first long axis and the second direction is less than 45 degrees, and an included angle between an extending direction of a third long axis of the third opening and the second direction is greater than 45 degrees.

### BACKGROUND OF THE DISCLOSURE

### 1. Field of the Disclosure

The present disclosure relates to an electronic device, and more particularly, to an electronic device with high resolution.

### 2. Description of the Prior Art

With the advancement of technology, a variety of electronic devices are provided. The electronic devices have become indispensable in modern life. However, the electronic devices have not yet met expectations in all aspects. With the enhancement of resolution and the reduction of pixel area, how to improve properties such as production yields of the electronic devices is one of the goals of the industry.

### SUMMARY OF THE DISCLOSURE

According to an embodiment of the present disclosure, an electronic device includes a substrate, a pixel defining layer and at least three light-emitting units. The pixel defining layer is disposed on the substrate. The pixel defining layer includes a first opening, a second opening and a third opening. The first opening, the second opening and the third opening respectively have a first long axis, a second long axis and a third long axis. The first opening and the second opening are arranged along a first direction, the first opening and the third opening are arranged along a second direction, and the first direction is different from the second direction. The at least three light-emitting units are respectively disposed in the first opening, the second opening and the third opening. An included angle between an extending direction of the first long axis and the first direction is greater than 45 degrees, an included angle between the extending direction of the first long axis and the second direction is less than 45 degrees, and an included angle between an extending direction of the third long axis and the second direction is greater than 45 degrees.

According to another embodiment of the present disclosure, an electronic device includes a substrate, a pixel defining layer and a plurality of light-emitting units. The substrate includes a plurality of pixel regions arranged in an array. The pixel defining layer is disposed on the substrate. The pixel defining layer includes a first groove extending along a first direction and spanning at least two of the plurality of pixel regions. The plurality of light-emitting units are disposed in the first groove along the first direction, and the plurality of light-emitting units are separated from at least one sidewall of the first groove.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a schematic diagram showing a partial top view of an electronic device according to an embodiment of the present disclosure.

FIG. 2 is a schematic diagram showing a partial top view of an electronic device according to another embodiment of the present disclosure.

FIG. 3 is a schematic diagram showing a partial top view of an electronic device according to further another embodiment of the present disclosure.

FIG. 4 is a schematic diagram showing a partial top view of an electronic device according to yet another embodiment of the present disclosure.

FIG. 5 is a schematic diagram showing a partial top view of an electronic device according to yet another embodiment of the present disclosure.

FIG. 6 is a schematic diagram showing a partial top view of an electronic device according to yet another embodiment of the present disclosure.

FIG. 7 is a schematic diagram showing a partial top view of an electronic device according to yet another embodiment of the present disclosure.

FIG. 8 is a schematic diagram showing a partial top view of an electronic device according to yet another embodiment of the present disclosure.

FIG. 9 is a schematic diagram showing a partial cross-sectional view of an electronic device according to yet another embodiment of the present disclosure.

### DETAILED DESCRIPTION

The present disclosure may be understood by reference to the following detailed description, taken in conjunction with the drawings as described below. Wherever possible, the same or similar parts in the drawings and descriptions are represented by the same reference numeral.

Certain terms are used throughout the description and following claims to refer to particular components. As one skilled in the art will understand, electronic equipment manufacturers may refer to a component by different names. This document does not intend to distinguish between components that differ in name but not function. In the following description and in the claims, the terms “include/comprise” and “have” are used in an open-ended fashion, and thus should be interpreted to mean “include, but not limited to . . . ”.

In the present disclosure, the directional terms, such as “on/up/above”, “down/below”, “front”, “rear/back”, “left”, “right”, etc., are only directions referring to the drawings. Therefore, the directional terms are used for explaining and not used for limiting the present disclosure. Regarding the drawings, the drawings show the general characteristics of methods, structures, and/or materials used in specific embodiments. However, the drawings should not be construed as defining or limiting the scope or properties encompassed by these embodiments. For example, for clarity, the relative size, thickness, and position of each layer, each area, and/or each structure may be reduced or enlarged.

In the present disclosure, when a structure (or layer, or component, or substrate) is described as located on/above another structure (or layer, or component, or substrate), it may refer that the two structures are adjacent and directly connected with each other, or the two structures are adjacent and indirectly connected with each other. The two structures being indirectly connected with each other may refer that at least one intervening structure (or intervening layer, or intervening component, or intervening substrate, or intervening interval) exists between the two structures, a lower surface of one of the two structure is adjacent or directly connected with an upper surface of the intervening structure, and an upper surface of the other of the two structures is adjacent or directly connected with a lower surface of the intervening structure. The intervening structure may be a single-layer or multi-layer physical structure or a non-physical structure, and the present disclosure is not limited thereto. In the present disclosure, when a certain structure is disposed “on/above” other structures, it may refer that the certain structure is “directly” disposed on/above the other structures, or the certain structure is “indirectly” disposed on/above the other structures, i.e., at least one structure is disposed between the certain structure and the other structures.

The terms “equal”, “identical/the same”, or “substantially/approximately” mentioned in this document generally mean being within 20% of a given value or range, or being within 10%, 5%, 3%, 2%, 1% or 0.5% of the given value or range.

Furthermore, any two values or directions used for comparison may have a certain error. If a first value is equal to a second value, it implies that there may be an error of about 10% between the first value and the second value; if a first direction is perpendicular or “substantially” perpendicular to a second direction, then an angle between the first direction and the second direction may be between 80 degrees to 100 degrees; if the first direction is parallel or “substantially” parallel to the second direction, an angle between the first direction and the second direction may be between 0 degree to 10 degrees.

Although ordinal numbers such as “first”, “second”, etc., may be used to describe elements in the description and the claims, it does not imply and represent that there have other previous ordinal number. The ordinal numbers do not represent the order of the elements or the manufacturing order of the elements. The ordinal numbers are only used for discriminate an element with a certain designation from another element with the same designation. The claims and the description may not use the same terms. Accordingly, a first element in the description may be a second element in the claims.

In addition, the term “a given range is from a first value to the second value” or “a given range falls within a range from a first value to a second value” refers that the given range includes the first value, the second value and other values therebetween.

Moreover, the electronic device of the present disclosure may include a display device, a backlight device, an antenna device, a sensing device, a tiled device, a touch display device, a curved display device or a free shape display device, but not limited thereto. The electronic device may exemplarily include liquid crystal, light emitting diode, fluorescence, phosphor, other suitable display media or a combination thereof, but not limited thereto. The display device may be a non-self-luminous type display device or a self-luminous type display device. The antenna device may be a liquid-crystal-type antenna device or a non-liquid-crystal-type antenna device. The sensing device may be a device for sensing capacitance, light, thermal or ultrasonic, but not limited thereto. The electronic components of the electronic device may include passive components and active components, such as capacitors, resistors, inductors, diodes, transistors, etc., but not limited thereto. The diode may include a light emitting diode (LED) or a photodiode. The light emitting diode may include organic light emitting diode (OLED), mini LED, micro LED or quantum dot LED, but not limited thereto. The tiled device may exemplarily be a tiled display device or a tiled antenna device, but not limited thereto. Furthermore, the electronic devices may be foldable or flexible electronic devices. The electronic device may be any combination of aforementioned devices, but not limited thereto. Furthermore, a shape of the electronic device may be a rectangle, a circle, a polygon, a shape with curved edge or other suitable shapes. The electronic device may have peripheral systems, such as a driving system, a control system, a light system, etc., for supporting the display device, the antenna device, the wearable device (for example, including augmented reality (AR) device or virtual reality (VR) device), the vehicle-mounted device (for example, including car windshields) or the tiled device.

In the present disclosure, it should be understood that a depth, a thickness, a width or a height of each element, or a space or a distance between elements may be measured by an optical microscopy (OM), a scanning electron microscope (SEM), a film thickness profiler (α-step), an ellipsometer or other suitable methods. In some embodiments, a cross-sectional image including elements to be measured can be obtained by the SEM, and the depth, the thickness, the width or the height of each element, or the space or the distance between elements can be measured thereby.

It should be noted that the technical features in different embodiments described in the following can be replaced, recombined, or mixed with one another to constitute another embodiment without departing from the spirit of the present disclosure.

Unless otherwise defined, all terms (including technical and scientific terms) used herein have the same meaning as commonly understood by a person having ordinary skill in the art to which the disclosure belongs. It can be understood that these terms, such as those defined in commonly used dictionaries, should be interpreted as having meanings consistent with the background or context of the related technology and the present disclosure, and should not be interpreted in an idealized or overly formal manner, unless otherwise specified in the disclosed embodiments.

In the present disclosure, the following drawings are described in conjunction with the XYZ Cartesian coordinate system for the sake of convenience. The direction Z may be, for example, parallel to a normal direction of the substrate of the electronic device.

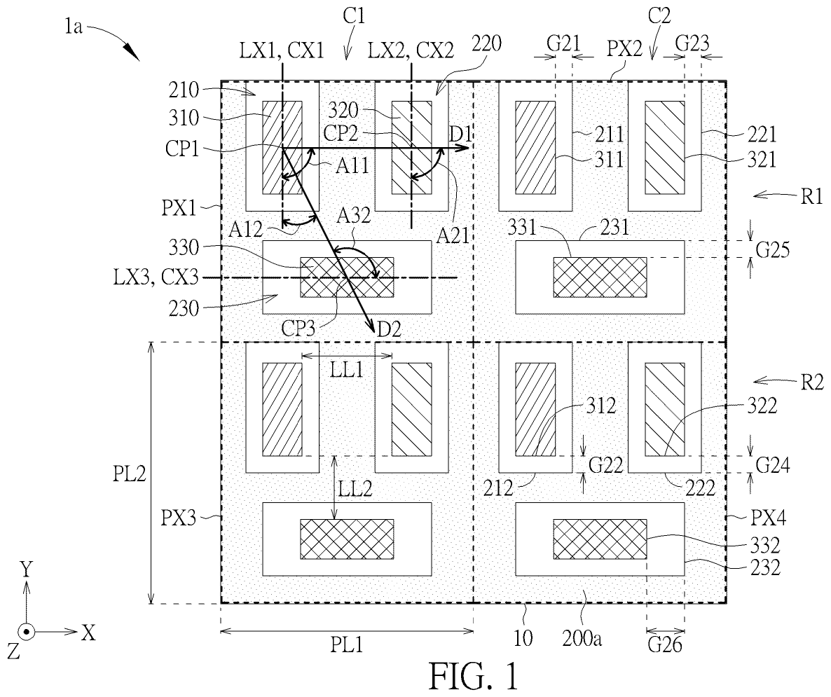

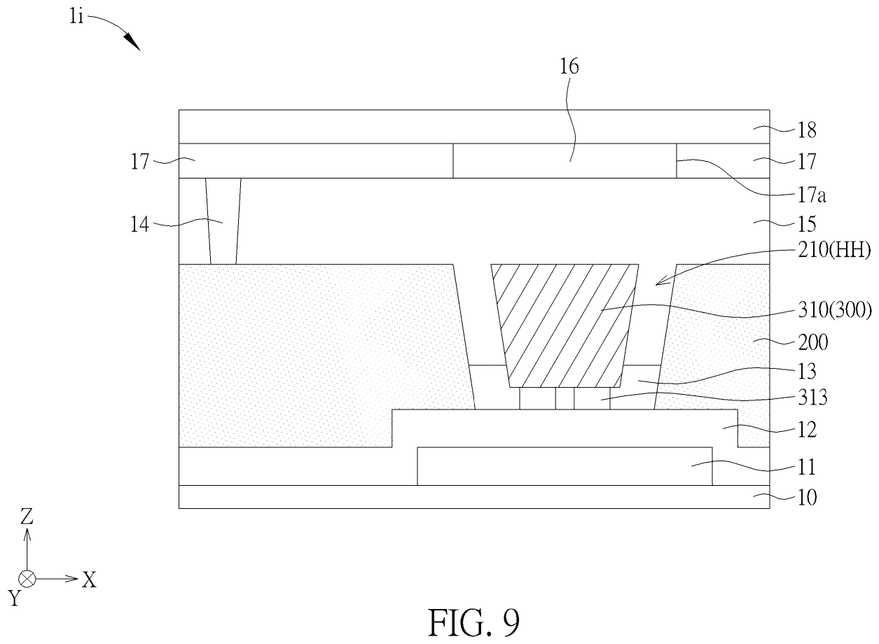

Please refer to FIG. 1, which is a schematic diagram showing a partial top view of an electronic device 1a according to an embodiment of the present disclosure. In the embodiment, the electronic device 1a is applied as a display device, but not limited thereto. The electronic device 1a may also include other functions, such as touch and detection, but not limited thereto. The electronic device 1a includes a substrate 10, a pixel defining layer 200a and at least three light-emitting units, such as a first light-emitting unit 310, a second light-emitting unit 320 and a third light-emitting unit 330. The pixel defining layer 200a is disposed on the substrate 10. The pixel defining layer 200a includes a first opening 210, a second opening 220 and a third opening 230. The first opening 210, the second opening 220 and the third opening 230 respectively have a first long axis LX1, a second long axis LX2 and a third long axis LX3. The first opening 210 and the second opening 220 are arranged along a direction D1, the first opening 210 and the third opening 230 are arranged along a direction D2, and the direction D1 is different from the direction D2. The at least three light-emitting units, such as the first light-emitting unit 310, the second light-emitting unit 320 and the third light-emitting unit 330 are respectively disposed in the first opening 210, the second opening 220 and the third opening 230. An included angle A11 between an extending direction of the first long axis LX1 and the direction D1 is greater than 45 degrees, an included angle A12 between the extending direction of the first long axis LX1 and the direction D2 is less than 45 degrees, and an included angle A32 between an extending direction of the third long axis LX3 and the direction D2 is greater than 45 degrees. With the configuration of the light-emitting units, the electronic device 1a may be applied as a high-resolution electronic device. Moreover, the electronic device 1a may provide the space for disposing the pixel defining layer 200a, which is favorable for enhancing the yield of the electronic device 1a. For example, the probability of the peeling of the light-emitting units or the probability that the light-emitting units are crushed by the photo spacer (such as the photo spacer 14 shown in FIG. 9) may be reduced.

Specifically, the electronic device 1a may include a plurality of pixel regions PX1, PX2, PX3 and PX4. The plurality of pixel regions PX1, PX2, PX3 and PX4 may be arranged in an array, in which the pixel region PX1 and the pixel region PX2 may be arranged along the direction X and located in the first horizontal row R1, the pixel region PX3 and the pixel region PX4 may be arranged along the direction X and located in the second horizontal row R2, the pixel region PX1 and the pixel region PX3 may be arranged along the direction Y and located in the first vertical row C1, and the pixel region PX2 and the pixel region PX4 may be arranged along the direction Y and located in the second vertical row C2, so as to form a 2×2 matrix. However, the present disclosure is not limited thereto.

The number of the pixel regions PX1, PX2, PX3, and PX4 of the electronic device 1a is exemplary and may be flexibly adjusted according to actual needs. Therefore, a matrix with the number of horizontal rows being greater than or equal to 2 and the number of vertical rows being greater than or equal to 2 may be formed.

In FIG. 1, a shape of each of the pixel regions PX1, PX2, PX3 and PX4 may be a square in the top view, but not limited thereto. Each of the pixel regions PX1, PX2, PX3 and PX4 may be configured in other shapes according to actual needs, such as triangle, cross, quadrangle, pentagon, hexagon, diamond, mosaic pattern or other suitable shapes, but not limited thereto. Each of the pixel regions PX1, PX2, PX3 and PX4 may have a first side length PL1 and a second side length PL2, and the following conditions may be satisfied: 10 μm≤PL1≤200 μm; and 10 μm≤PL2≤200 μm. Thereby, it is favorable for the electronic device 1a being applied as a high-resolution electronic device. Herein, the electronic device 1a is exemplary a flat electronic device, but not limited thereto. In other embodiments of the present disclosure, the electronic device 1a may be a non-flat electronic device such as a curved electronic device.

Each of the first opening 210, the second opening 220 and the third opening 230 may have a rectangular shape in the top view. The first opening 210 may have two first sidewalls 211 and two second sidewalls 212. The first sidewalls 211 correspond to the long sides of the rectangular shape, the second sidewalls 212 correspond to the short sides of the rectangular shape, and the first long axis LX1 may be parallel to the first sidewalls 211. The second opening 220 may have two first sidewalls 221 and two second sidewalls 222. The first sidewalls 221 correspond to the long sides of the rectangular shape, the second sidewalls 222 correspond to the short sides of the rectangular shape, and the second long axis LX2 may be parallel to the first sidewalls 221. The third opening 230 may have two first sidewalls 231 and two second sidewalls 232. The first sidewalls 231 correspond to the long sides of the rectangular shape, the second sidewalls 232 correspond to the short sides of the rectangular shape, and the third long axis LX3 may be parallel to the first sidewalls 231. The first long axis LX1 is, for example, parallel to the direction Y. The second long axis LX2 is, for example, parallel to the direction Y. The third long axis LX3 is, for example, parallel to the direction X. That is, the first long axis LX1 are parallel to the second long axis LX2, and the first long axis LX1 and the second long axis LX2 are perpendicular to the third long axis LX3.

The first opening 210 has a first central point CP1, the second opening 220 has a second central point CP2, and the third opening 230 has a third central point CP3. The aforementioned direction D1 may be defined as a direction from the first central point CP1 to the second central point CP2. The aforementioned direction D2 may be defined as a direction from the first central point CP1 to the third central point CP3. Herein, the direction D1 is exemplarily parallel to the direction X and perpendicular to the direction Y, and the direction D2 is exemplarily between the direction X and the direction Y.

The aforementioned included angle A11 between the extending direction of the first long axis LX1 and the direction D1 may be defined as an included angle from the extending direction of the first long axis LX1 to the direction D1 along the counterclockwise direction. Herein, the included angle A11 is greater than 45 degrees. More specifically, the included angle A11 is equal to 90 degrees. The included angle A12 between the extending direction of the first long axis LX1 and the direction D2 may be defined as an included angle from the extending direction of the first long axis LX1 to the direction D2 along the counterclockwise direction. Herein, the included angle A12 is greater than 0 degrees and less than 45 degrees. The aforementioned included angle A32 between the extending direction of the third long axis LX3 and the direction D2 may be defined as an included angle from the extending direction of the third long axis LX3 to the direction D2 along the counterclockwise direction. Herein, the included angle A32 is greater than 45 degrees. More specifically, the included angle A32 is greater than 90 degrees. In addition, in the embodiment, the included angle A21 between the extending direction of the second long axis LX2 and the direction D1 is greater than 45 degrees. The included angle A21 between the extending direction of the second long axis LX2 and the direction D1 may be defined as an included angle from the extending direction of the second long axis LX2 to the direction D1 along the counterclockwise direction. Herein, the included angle A21 is greater than 45 degrees. More specifically, the included angle A21 is equal to 90 degrees.

Each of the first light-emitting unit 310, the second light-emitting unit 320 and the third light-emitting unit 330 may have a rectangular shape in the top view. The first light-emitting unit 310 may have a first central long axis CX1, and have two first sides 311 and two second sides 312. The first sides 311 correspond to the long sides of the rectangular shape, the second sides 312 correspond to short sides of the rectangular shape, and the first sides 311 may be parallel to the first central long axis CX1. The second light-emitting unit 320 may have a second central long axis CX2, and have two first sides 321 and two second sides 322. The first sides 321 correspond to the long sides of the rectangular shape, the second sides 322 correspond to the short sides of the rectangular shape, and the first sides 321 may be parallel to the second central long axis CX2. The third light-emitting unit 330 may have a third central long axis CX3, and have two first sides 331 and two second sides 332. The first sides 331 correspond to the long sides of the rectangular shape, the second sides 332 correspond to the short sides of the rectangular shape, and the first sides 331 may be parallel to the third central long axis CX3.

The first light-emitting unit 310 is disposed in the first opening 210. The first central long axis CX1 of the first light-emitting unit 310 may, for example, coincide with the first long axis LX1 of the first opening 210. The second light-emitting unit 320 is disposed in the second opening 220. The second central long axis CX2 of the second light-emitting unit 320 may, for example, coincide with the second long axis LX2 of the second opening 220. The third light-emitting unit 330 is disposed in the third opening 230. The third central long axis CX3 of the third light-emitting unit 330 may, for example, coincide with the third long axis LX3 of the third opening 230. However, the present disclosure is not limited thereto. In some embodiments, the first central long axis CX1 and the first long axis LX1 may not coincide with each other. For example, the first central long axis CX1 and the first long axis LX1 may be parallel to each other along the direction X, or may intersect each other. Similarly, the second central long axis CX2 and the second long axis LX2 may not coincide with each other. For example, the second central long axis CX2 and the second long axis LX2 may be parallel to each other along the direction X, or may intersect each other. Similarly, the third central long axis CX3 and the third long axis LX3 may not coincide with each other. For example, the third central long axis CX3 and the third long axis LX3 may be parallel to each other along the direction Y, or may intersect each other.

The first light-emitting unit 310, the second light-emitting unit 320 and the third light-emitting unit 330 may be respectively separated from at least one sidewall (such as the first sidewalls 211 and the second sidewalls 212) of the first opening 210, at least one sidewall (such as the first sidewalls 221 and the second sidewalls 222) of the second opening 220 and at least one sidewall (such as the first sidewalls 231 and the second sidewalls 232) of the third opening 230, and there are spaced distances (such as the spaced distances G21, G22, G23, G24, G25 and G26) respectively between the first light-emitting unit 310, the second light-emitting unit 320 and the third light-emitting unit 330 and the at least one sidewall of the first opening 210, the at least one sidewall of the second opening 220 and the at least one sidewall of the third opening 230. The spaced distances may be greater than or equal to 5 μm.

In the embodiment, the first light-emitting unit 310 is separated from the two first sidewalls 211 and the two second sidewalls 212 of the first opening 210. There is a spaced distance G21 between the first side 311 of the first light-emitting unit 310 and the first sidewall 211 of the first opening 210, and there is a spaced distance G22 between the second side 312 of the first light-emitting unit 310 and the second sidewall 212 of the first opening 210. The second light-emitting unit 320 is separated from the two first sidewalls 221 and the two second sidewalls 222 of the second opening 220. There is a spaced distance G23 between the first side 321 of the second light-emitting unit 320 and the first sidewall 221 of the second opening 220, and there is a spaced distance G24 between the second side 322 of the second light-emitting unit 320 and the second sidewall 222 of the second opening 220. The third light-emitting unit 330 is separated from the two first sidewalls 231 and the two second sidewalls 232 of the third opening 230. There is a spaced distance G25 between the first side 331 of the third light-emitting unit 330 and the first sidewall 231 of the third opening 230, and there is a spaced distance G26 between the second side 332 of the third light-emitting unit 330 and the second sidewall 232 of the third opening 230. The spaced distances G21, G22, G23, G24, G25 and G26 may be greater than or equal to 5 μm. Moreover, the lengths of the spaced distances G21, G22, G23, G24, G25 and G26 may be independent from each other. That is, any two of the spaced distances G21, G22, G23, G24, G25 and G26 may be the same or different.

In FIG. 1, the central point (not labeled) of the first light-emitting unit 310 coincides with the first central point CP1 of the first opening 210. That is, the spaced distance G21 between the first side 311 on the left of the first light-emitting unit 310 and the first sidewall 211 on the left of the first opening 210 is equal to the spaced distance G21 between the first side 311 on the right of the first light-emitting unit 310 and the first sidewall 211 on the right of the first opening 210, and the spaced distance G22 between the second side 312 on the top of the light-emitting unit 310 and the second sidewall 212 on the top of the first opening 210 is equal to the spaced distance G22 between the second side 312 on the bottom of the light-emitting unit 310 and the second sidewall 212 on the bottom of the first opening 210. However, it is only exemplary. In other embodiment, the central point (not labeled) of the first light-emitting unit 310 may not coincide with the first central point CP1 of the first opening 210. That is, the spaced distances G21 on the left and right sides of the first light-emitting unit 310 may be unequal, and the spaced distances G22 on the upper and lower sides of the first light-emitting unit 310 may be unequal.

Similarly, the central point (not labeled) of the second light-emitting unit 320 may or may not coincide with the second central point CP2 of the second opening 220, so that the spaced distances G23 on the left and right sides of the second light-emitting unit 320 may be equal or unequal, and the spaced distances G24 on the upper and lower sides of the second light-emitting unit 320 may be equal or unequal. Similarly, the central point (not labeled) of the third light-emitting unit 330 may or may not coincide with the third central point CP3 of the third opening 230, so that the spaced distances G25 on the upper and lower sides of the third light-emitting unit 330 may be equal or unequal, and the spaced distances G26 on the left and right sides of the third light-emitting unit 330 may be equal or unequal.

In some embodiments, the first light-emitting unit 310, the second light-emitting unit 320 and the third light-emitting unit 330 may be tightly adjacent to at least one sidewall of the first opening 210, at least one sidewall of the second opening 220 and at least one sidewall of the third opening 230, respectively. That is, there may be no spaced distance (i.e., the spaced distance is equal to 0) between the first light-emitting unit 310, the second light-emitting unit 320 and the third light-emitting unit 330 and the at least one sidewall (such as the first sidewalls 211 and the second sidewalls 212) of the first opening 210, the at least one sidewall (such as the first sidewalls 221 and the second sidewalls 222) of the second opening 220 and the at least one sidewall (such as the first sidewalls 231 and the second sidewalls 232) of the third opening 230. In some embodiments, the first light-emitting unit 310, the second light-emitting unit 320 and the third light-emitting unit 330 may be tightly adjacent to all the sidewalls of the first opening 210, all the sidewalls of the second opening 220 and all the sidewalls of the third opening 230, respectively. In some embodiments, the spaced distances G21, G22, G23, G24, G25 and G26 may be independently greater than or equal to 0 and less than or equal to 5 μm. Alternatively, the spaced distances G21, G22, G23, G24, G25 and G26 may be independently greater than or equal to 1 μm and less than or equal to 5 μm.

In FIG. 1, the spaced distance LL1 between two adjacent light-emitting units (such as the first light-emitting unit 310 and the second light-emitting unit 320) in the first horizontal direction (such as the direction X) may satisfy the following condition: 0 μm≤LL1≤20 μm. The spaced distance LL2 between two adjacent light-emitting units (such as the first light-emitting unit 310 and the third light-emitting unit 330 or the second light-emitting unit 320 and the third light-emitting unit 330) in the second horizontal direction (such as the direction Y) may satisfy the following condition: 0 μm≤LL2≤20 μm. Thereby, the arrangement of the light-emitting units is more compact, which is favorable for the electronic device 1a being applied as a high-resolution electronic device.

The first light-emitting unit 310 disposed in the first opening 210 is exemplary a red light-emitting unit, the second light-emitting unit 320 disposed in the second opening 220 is exemplary a green light-emitting unit, and the third light-emitting unit 330 disposed in the third opening 230 is exemplary a blue light-emitting unit, but not limited thereto. The colors of the first light-emitting unit 310, the second light-emitting unit 320 and the third light-emitting unit 330 may be flexibly adjusted according to actual needs.

In the embodiment, the number, the colors and the arrangement of the light-emitting units (such as the first light-emitting unit 310, the second light-emitting unit 320 and the third light-emitting unit 330) in the pixel regions PX1, PX2, PX3 and PX4 are all the same.

However, it is only exemplary. The shapes, number, types and arrangement of the light-emitting units and/or the openings (such as the first opening 210, the second opening 220 and the third opening 230) in each of the pixel regions PX1, PX2, PX3 and PX4 may be flexibly adjusted according to actual needs. In some embodiments, the shapes of each of the light-emitting units and/or the openings in each of the pixel regions PX1, PX2, PX3 and PX4 may also be a circle. In this way, each of the aforementioned first central point CP1 to the third central point CP3 may be at the center of the circle, and each of the first central long axis CX1 to the third central long axis CX3 and each of the first long axis LX1 to the third long axis LX3 may be at the diameter of the circle.

The substrate 10 may be a rigid or flexible substrate. The material of the substrate 10 may include, for example, glass, ceramic, sapphire, plastic, other suitable materials, or a combination thereof, but not limited thereto. In some embodiments, the substrate 10 may be a single-layer structure or a multi-layer structure. For example, when the substrate 10 is a multi-layer structure, the substrate 10 may include at least one inorganic layer (not shown) and at least one organic layer (not shown) stacked alternately. The organic layer may include, for example, polyimide (PI), polyethylene terephthalate (PET), adhesive, other suitable materials, or a combination thereof, but not limited thereto. The inorganic layer may include, for example, silicon oxide, silicon nitride, other suitable materials, or a combination thereof, but not limited thereto.

The material of the pixel defining layer 200 may include resin, an acrylic material, a photoresist material, other suitable materials, or a combination thereof, but not limited thereto. The photoresist material may include, for example, a positive photoresist material or a negative photoresist material. In addition, the material of the pixel defining layer 200a may include an absorbing material, a reflective material or a transparent material. The absorbing material may include, for example, a black or gray photoresist, other suitable materials, or a combination thereof. The reflective material may include, for example, a white photoresist, a white paint, a white glue, other suitable materials, or a combination thereof. In other words, the color of the pixel defining layer 200a may include white, black, transparent, other suitable colors or a combination thereof. When the material of the pixel defining layer 200a includes the reflective material, the pixel defining layer 200a may reflect the light of the light-emitting unit, so that the light emitted from the light-emitting unit may be more concentrated. When the material of the pixel defining layer 200a includes the absorbing material, the pixel defining layer 200a may absorb the reflected light of the light-emitting unit and reduce the probability that the light of the light-emitting unit travel to other pixel regions PX1, PX2, PX3 and PX4 to cause the color mixture. When the material of the pixel defining layer 200a includes the transparent material, the pixel defining layer 200a can support the photo spacer (see the photo spacer 14 in FIG. 9), so as to maintain a better thickness of the cell gap and stabilize the evenness of the height of the optical clear resin (OCR, see the optical clear resin 15 in FIG. 9).

The first light-emitting unit 310, the second light-emitting unit 320 and the third light-emitting unit 330 may be dies or chips, and may include diodes, such as light emitting diodes (LEDs) or photodiodes. The light emitting diodes may include, for example, organic light emitting diodes (OLEDs), mini LEDs, micro LEDs or quantum dot LEDs, but not limited thereto.

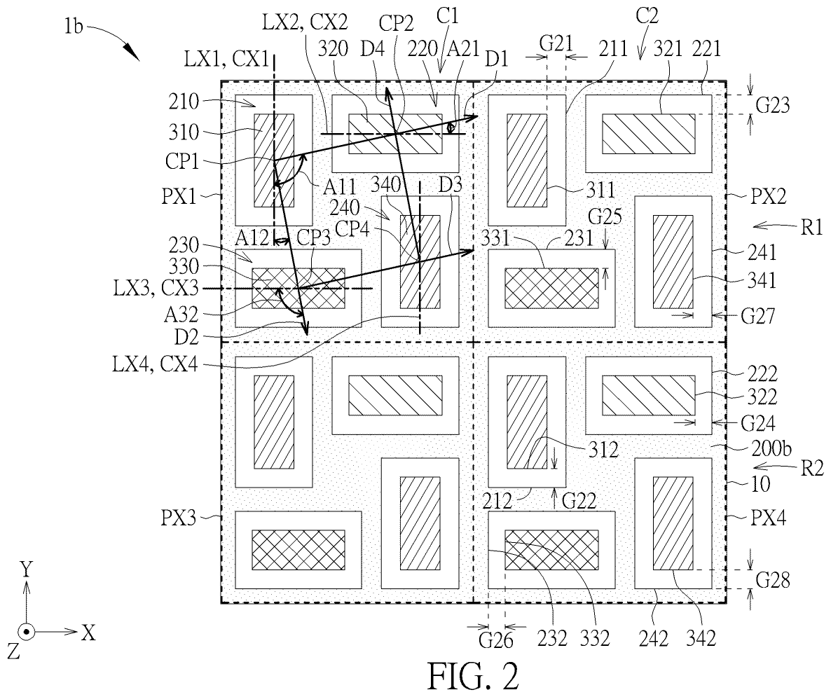

Please refer to FIG. 2, which is a schematic diagram showing a partial top view of an electronic device according to another embodiment of the present disclosure. The similarities between the electronic device 1b and the electronic device 1a are not repeated herein, and the differences therebetween include the number of the openings of the pixel defining layer 200b, the number of the light-emitting units, and the configuration of the openings and the light-emitting units. Compared with the electronic device 1a, the pixel defining layer 200b of the electronic device 1b further includes a fourth opening 240, and the electronic device 1b further includes a fourth light-emitting unit 340 disposed in the fourth opening 240.

The first opening 210, the second opening 220, the third opening 230 and the fourth opening 240 respectively have a first long axis LX1, a second long axis LX2, a third long axis LX3 and a fourth long axis LX4. The first opening 210 and the second opening 220 are arranged along the direction D1, the first opening 210 and the third opening 230 are arranged along the direction D2, the third opening 230 and the fourth opening 240 are arranged along the direction D3, and the fourth opening 240 and the second opening 220 are arranged along the direction D4. The direction D2 is different from the direction D1, the direction D3 is different from the direction D2, the direction D4 is different from the direction D3, the direction D3 is parallel to the direction D1, and the direction D4 is parallel to the direction D2. Therefore, the third opening 230 and the fourth opening 240 may be regarded as being arranged along the direction D1. The included angle A11 between the extending direction of the first long axis LX1 and the direction D1 is greater than 45 degrees, the included angle A12 between the extending direction of the first long axis LX1 and the direction D2 is less than 45 degrees, and the included angle A32 between the extending direction of the third long axis LX3 and the direction D2 is greater than 45 degrees. Furthermore, in the embodiment, the included angle A21 between the extending direction of the second long axis LX2 and the direction D1 is less than 45 degrees. Regarding the definitions of the included angles A11, A12, A32 and A21, references may be made to the above relevant description and are not repeated herein. Furthermore, although the included angle between any of the first long axis LX1, the second long axis LX2, the third long axis LX3 and the fourth long axis LX4 and any of the directions D1, D2, D3 and D4 is not listed one by one, the definition of the included angle between any of the first long axis LX1, the second long axis LX2, the third long axis LX3 and the fourth long axis LX4 and any of the directions D1, D2, D3, D4 may be similar to that of the included angles A11, A12, A32 and A21, and is not repeated herein.

The first opening 210 has a first central point CP1, the second opening 220 has a second central point CP2, the third opening 230 has a third central point CP3 and the fourth opening 240 has a fourth central point CP4. The aforementioned direction D1 may be defined as the direction from the first central point CP1 to the second central point CP2. The aforementioned direction D2 may be defined as the direction from the first central point CP1 to the third central point CP3. The aforementioned direction D3 may be defined as the direction from the third central point CP3 to the fourth central point CP4, and the aforementioned direction D4 may be defined as the direction from the fourth central point CP4 to the second central point CP2. Herein, the directions D1, D2, D3 and D4 are exemplary as directions between the direction X and the direction Y.

In the embodiment, the first long axis LX1 is parallel to the direction Y, the second long axis LX2 is parallel to the direction X, the third long axis LX3 is parallel to the direction X, and the fourth long axis LX4 is parallel to the direction Y. That is, the first long axis LX1 and the fourth long axis LX4 are parallel to each other, the second long axis LX2 and the third long axis LX3 are parallel to each other, and the first long axis LX1 and the fourth long axis LX4 are perpendicular to the second long axis LX2 and the third long axis LX3.

The fourth opening 240 has two first sidewalls 241 and two second sidewalls 242. The first sidewalls 241 correspond to the long sides of the rectangular shape, the second sidewalls 242 correspond to the short sides of the rectangular shape, and the fourth long axis LX4 is parallel to the first sidewalls 241. The fourth light-emitting unit 340 has a rectangular shape in the top view. The fourth light-emitting unit 340 may have a fourth central long axis CX4, and have two first sides 341 and two second sides 342. The first sides 341 correspond to the long sides of the rectangular shape, the second sides 342 correspond to the short sides of the rectangular shape, and the first side 341 may be substantially parallel to the fourth central long axis CX4.

The fourth light-emitting unit 340 may be separated from at least one sidewall (such as the first sidewalls 241 and the second sidewalls 242) of the fourth opening 240. There may be a spaced distance (such as the spaced distances G27 and G28) between the fourth light-emitting unit 340 and the least one sidewall of the fourth opening 240, and the spaced distance may be greater than or equal to 5 μm. In the embodiment, the fourth light-emitting unit 340 is separated from the two first sidewalls 241 and the two second sidewalls 242 of the fourth opening 240. There is a spaced distance G27 between the first side 341 of the fourth light-emitting unit 340 and the first sidewall 241 of the fourth opening 240, and the spaced distance G27 may be greater than or equal to 5 μm. There is a spaced distance G28 between the second side 342 of the fourth light-emitting unit 340 and the second sidewall 242 of the fourth opening 240, and the spaced distance G28 may be greater than or equal to 5 μm.

In FIG. 2, the central point (not labeled) of the fourth light-emitting unit 340 coincides with the fourth central point CP4 of the fourth opening 240. That is, the spaced distances G27 on the left and right sides of the fourth light-emitting unit 340 may be equal, and the spaced distances G28 on the upper and lower sides of the fourth light-emitting unit 340 may be equal, but not limited thereto. In other embodiments, the central point (not labeled) of the fourth light-emitting unit 340 may not coincide with the fourth central point CP4 of the fourth opening 240. That is, the spaced distances G27 on the left and right sides of the fourth light-emitting unit 340 may be unequal, and the spaced distances G28 on the upper and lower sides of the fourth light-emitting unit 340 may be unequal.

The first light-emitting unit 310 is disposed in the first opening 210, and is exemplary a red light-emitting unit. The second light-emitting unit 320 is disposed in the second opening 220, and is exemplary a green light-emitting unit. The third light-emitting unit 330 is disposed in the third opening 230, and is exemplary a blue light-emitting unit. The fourth light-emitting unit 340 is disposed in the fourth opening 240, and is exemplary a red light-emitting unit. That is, in the embodiment, the first light-emitting unit 310 and the fourth light-emitting unit 340 are the same. In the embodiment, there are two red light-emitting units disposed in the same pixel regions PX1, PX2, PX3 and PX4. It can also be regarded that the number of the red light-emitting units is greater than the number of the blue light-emitting unit and the number of the green light-emitting unit in the same pixel regions PX1, PX2, PX3 and PX4. Thereby, the problems such as color shift caused by the low luminous efficiency of the red light-emitting units (such as red LEDs) can be improved. In some embodiments, the first light-emitting units 310 and the fourth light-emitting units 340 may also be green light-emitting units, blue light-emitting units or light-emitting units with other suitable colors, but not limited thereto.

Furthermore, in the embodiment, the number, colors, and arrangement of the light-emitting units in the pixel regions PX1, PX2, PX3 and PX4 are all the same. However, it is only exemplary. The number, types and arrangement of the light-emitting units in each of the pixel regions PX1, PX2, PX3 and PX4 may be flexibly adjusted according to actual needs. For other details of the electronic device 1b, references may be made to the relevant description of the electronic device 1a mentioned above, and are not repeated herein. In some embodiments, the shape of each of the light-emitting units and/or the openings in each of the pixel regions PX1, PX2, PX3 and PX4 may also be a circle. In this way, each of the aforementioned first central point CP1 to the fourth central point CP4 may be at the center of the circle, and each of the first central long axis CX1 to the fourth central long axis CX4 and the first long axis LX1 to the fourth long axis LX4 may be at the diameter of the circle.

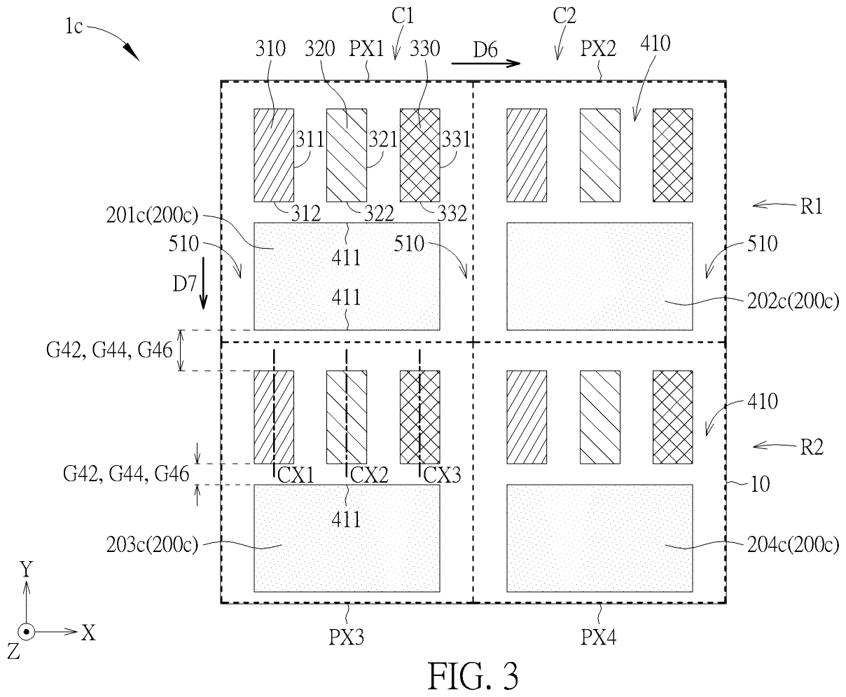

Please refer to FIG. 3, which is a schematic diagram showing a partial top view of an electronic device according to further another embodiment of the present disclosure. The electronic device 1c includes a substrate 10, a pixel defining layer 200c and a plurality of light-emitting units, such as a first light-emitting unit 310, a second light-emitting unit 320 and a third light-emitting unit 330. The substrate 10 includes a plurality of pixel regions PX1, PX2, PX3 and PX4, and the plurality of pixel regions PX1, PX2, PX3 and PX4 are arranged in an array. The pixel defining layer 200c is disposed on the substrate 10. The pixel defining layer 200c includes grooves 410. The groove 410 extends along the direction D6 and spans at least two of the plurality of pixel regions PX1, PX2, PX3 and PX4. Herein, the groove 410 located at the upper position spans the two pixel regions PX1 and PX2, and the groove 410 located at the lower position spans the two pixel regions PX3 and PX4, which is exemplary.

The plurality of light-emitting units (such as the first light-emitting unit 310, the second light-emitting unit 320 and the third light-emitting unit 330) are arranged in the groove 410 along the direction D6, and the plurality of light-emitting units (such as the first light-emitting unit 310, the second light-emitting unit 320 and the third light-emitting unit 330) are separated from at least one sidewall 411 of the groove 410. With the configuration of the light-emitting units, it is favorable for the electronic device 1c being applied as a high-resolution electronic device. Moreover, the electronic device 1c may provide the space for disposing the pixel defining layer 200c, which is favorable for enhancing the yield of the electronic device 1c. For example, the probability of the peeling of the light-emitting units or the probability that the light-emitting units are crushed by the photo spacer may be reduced.

The plurality of pixel regions PX1, PX2, PX3 and PX4 may be arranged to form a 2×2 array. For other details of the pixel regions PX1, PX2, PX3 and PX4, references may be made to the relevant description of the electronic device 1a.

The groove 410 may have a rectangular shape in the top view, and the groove 410 may have two sidewalls 411 parallel to the direction D6. For example, the direction D6 may be parallel to the direction X. In the present disclosure, the main difference between the groove 410 and the opening (such as the first opening 210, the second opening 220 and the third opening 230 in FIG. 1) is the opening being formed in one of the pixel regions PX1, PX2, PX3 and PX4, while the groove 410 spanning at least two pixel regions PX1, PX2, PX3 and PX4.

In FIG. 3, each of the pixel regions PX1, PX2, PX3 and PX4 includes, for example, three light-emitting units, which are the first light-emitting unit 310, the second light-emitting unit 320 and the third light-emitting unit 330. The first light-emitting unit 310, the second light-emitting unit 320 and the third light-emitting unit 330 are sequentially arranged in the groove 410 along the direction D6. Moreover, the first central long axis CX1 of the first light-emitting unit 310, the second central long axis CX2 of the second light-emitting unit 320 and the third central long axis CX3 of the third light emitting unit 330 may be perpendicular to the direction D6. The first light-emitting unit 310 is exemplary a red light-emitting unit, the second light-emitting unit 320 is exemplary a green light-emitting unit, and the third light-emitting unit 330 is exemplary a blue light-emitting unit. Since the groove 410 extends along the direction D6 and spans at least two of the plurality of pixel regions PX1, PX2, PX3 and PX4, the red light-emitting units, the green light-emitting units and the blue light-emitting units are arranged alternately in the groove 410 along the direction D6. In the embodiment, the number, colors and arrangement of the light-emitting units in the pixel regions PX1, PX2, PX3 and PX4 are all the same. However, it is only exemplary. The number, types and arrangement of the light-emitting units in each of the pixel regions PX1, PX2, PX3 and PX4 may be flexibly adjusted according to actual needs.

In the same pixel regions PX1, PX2, PX3 and PX4, the pixel defining layer 200c is not disposed between two adjacent light-emitting units (such as the first light-emitting unit 310 and the second light-emitting unit 320, or the second light-emitting unit 320 and the third light-emitting unit 330). In the same groove 410, the pixel defining layer 200c is not disposed between two adjacent light-emitting units (such as the first light-emitting unit 310 and the second light-emitting unit 320, the second light-emitting unit 320 and the third light-emitting unit 330 or the third light-emitting unit 330 and the first light-emitting unit 310) along the direction D6.

The first light-emitting unit 310 is separated from the two sidewalls 411 of the groove 410. There is a spaced distance G42 between the second side 312 of the first light-emitting unit 310 and the sidewall 411 of the groove 410. The second light-emitting unit 320 is separated from the two sidewalls 411 of the groove 410. There is a spaced distance G44 between the second side 322 of the second light-emitting unit 320 and the sidewall 411 of the groove 410. The third light-emitting unit 330 is separated from the two sidewalls 411 of the groove 410. There is a spaced distance G46 between the second side 332 of the third light-emitting unit 330 and the sidewall 411 of the groove 410. The spaced distances G42, G44 and G46 may be greater than or equal to 5 μm. However, the present disclosure is not limited thereto. The spaced distances G42, G44 and G46 may independently be greater than or equal to 1 μm and less than or equal to 5 μm. In FIG. 3, the spaced distances G42, G44 and G46 are the same, which is exemplary, and the present disclosure is not limited thereto. The lengths of the spaced distances G42, G44 and G46 may be independent from each other. That is, any two of the spaced distances G42, G44 and G46 may be the same or different.

In FIG. 3, the spaced distances G42 on the upper and lower sides of the first light-emitting unit 310 are unequal, the spaced distances G44 on the upper and lower sides of the second light-emitting unit 320 are unequal, and the spaced distances G46 on the upper and lower sides of the third light-emitting unit 330 are unequal. However, in other embodiments, the spaced distances G42 on the upper and lower sides of the first light-emitting unit 310 may be equal to each other, the spaced distances G44 on the upper and lower sides of the second light-emitting unit 320 may be equal to each other, and the spaced distances G46 on the upper and lower sides of the third light-emitting unit 330 may be equal to each other.

In FIG. 3, the pixel defining layer 200c may further include grooves 510. The groove 510 extends along the direction D7 and spans at least two of the plurality of pixel regions PX1, PX2, PX3 and PX4. For example, three grooves 510 are shown in FIG. 3. The groove 510 located at the left position extends along the direction D7 and spans the two pixel regions PX1 and PX3. The groove 510 located at the middle position extends along the direction D7 and spans the two pixel regions PX1 and PX3 and the two pixel regions PX2 and PX4. The groove 510 located at the right position extends along the direction D7 and spans the two pixel regions PX2 and PX4. Moreover, the direction D6 is perpendicular to the direction D7. With the groove 510, the portions of the pixel defining layer 200c in different pixel regions PX1, PX2, PX3 and PX4 may be separated from each other along the direction D6. For example, the pixel defining layer 201c in the pixel region PX1 has a rectangular shape, the pixel defining layer 202c in the pixel region PX2 has a rectangular shape, and the groove 510 is disposed between the pixel defining layers 201c and 202c to separate the pixel defining layer 201c from the pixel defining layer 202c. Similarly, the pixel defining layer 203c in the pixel region PX3 has a rectangular shape, the pixel defining layer 204c in the pixel region PX4 has a rectangular shape, and the groove 510 is disposed between the pixel defining layers 203c and 204c to separate the pixel defining layer 203c from the pixel defining layer 204c. However, the present disclosure is not limited thereto. In other embodiments, the portions of the pixel defining layers 200c in different pixel regions PX1, PX2, PX3 and PX4 may be connected with each other along the direction D6. For example, the pixel defining layer 200c may not be disposed with the grooves 510, so that the pixel defining layer 201c in the pixel region PX1 and the pixel defining layer 202c in the pixel region PX2 are connected with each other along the direction D6, and the total length of the pixel defining layer 201c and the pixel defining layer 202c are the same as the length of the groove 410 in the direction D6. The pixel defining layer 203c in the pixel region PX3 and the pixel defining layer 204c in the pixel region PX4 are connected with each other along the direction D6, and the total length of the pixel defining layer 203c and the pixel defining layer 204c are the same as the length of the groove 410 in the direction D6. For other details of the electronic device 1c, references may be made to the relevant descriptions of the electronic devices 1a and 1b mentioned above, and are not repeated herein.

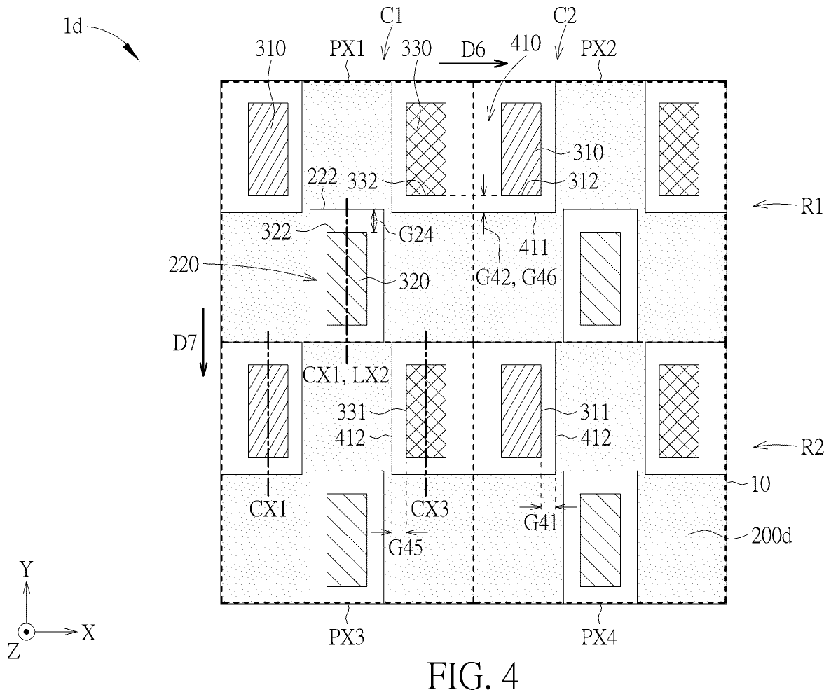

Please refer to FIG. 4, which is a schematic diagram showing a partial top view of an electronic device according to yet another embodiment of the present disclosure. The main differences between the electronic device 1d and the electronic device 1c are the configuration of the grooves 410 in the pixel defining layer 200d, the pixel defining layer 200d further including a second opening 220 and the configuration of the light-emitting units. The pixel defining layer 200d includes grooves 410. The groove 410 extends along the direction D6 and spans at least two of the plurality of pixel regions PX1, PX2, PX3 and PX4. Herein, the groove 410 located at the upper position spans the two pixel regions PX1 and PX2, and the groove 410 located at the lower position spans the two pixel regions PX3 and PX4, which is exemplary. A plurality of light-emitting units (such as the third light-emitting unit 330 and the first light-emitting unit 310) are arranged in the groove 410 along the direction D6, and the plurality of light-emitting units (such as the third light-emitting unit 330 and the first light-emitting unit 310) are separated from at least one sidewall 411 of the groove 410.

The groove 410 may have a rectangular shape in the top view, and the groove 410 may have two sidewalls 411 parallel to the direction D6 and two sidewalls 412 parallel to the direction D7. For example, the direction D6 may be parallel to the direction X, and the direction D7 may be parallel to direction Y. The pixel defining layer 200d may further include a second opening 220, and the second long axis LX2 of the second opening 220 may be parallel to the direction Y. That is, the second long axis LX2 of the second opening 220 may be perpendicular to the direction D6. Moreover, the second opening 220 is staggered with the groove 410 along the direction D6. The phrase “the second opening 220 being staggered with the groove 410 along the direction D6” refers that the second opening 220 is not completely aligned with the groove 410 along the direction D6, which includes the second opening 220 being completely misaligned with the groove 410 along the direction D6. Each of the pixel regions PX1, PX2, PX3 and PX4 includes, for example, three light-emitting units, which are the first light-emitting unit 310, the second light-emitting unit 320 and the third light-emitting unit 330. The third light-emitting unit 330 and the first light-emitting unit 310 are sequentially arranged in the groove 410 along the direction D6. The second light emitting unit 320 may be disposed in the second opening 220. Regarding the arrangement relationship between the second light-emitting unit 320 and the second opening 220, references may be made to the relevant description of FIG. 1, and are not repeated herein. The third central long axis CX3 of the third light-emitting unit 330 and the first central long axis CX1 of the first light-emitting unit 310 may be perpendicular to the direction D6. The first light-emitting unit 310 is exemplary a red light-emitting unit, the second light-emitting unit 320 is exemplary a green light-emitting unit, and the third light-emitting unit 330 is exemplary a blue light-emitting unit. In the embodiment, the number, colors, and arrangement of the light-emitting units in the pixel regions PX1, PX2, PX3 and PX4 are all the same. However, it is only exemplary. The number, types and arrangement of the light-emitting units in each of the pixel regions PX1, PX2, PX3 and PX4 may be flexibly adjusted according to actual needs.

In the same pixel regions PX1, PX2, PX3 and PX4, the pixel defining layer 200d is disposed between two adjacent light-emitting units (such as the first light-emitting unit 310 and the third light-emitting unit 330). In the same groove 410, the pixel defining layer 200d is not disposed between two adjacent light-emitting units (such as the third light-emitting unit 330 and the first light-emitting unit 310) along the direction D6.

The third light-emitting unit 330 is separated from the two sidewalls 411 and the two sidewalls 412 of the groove 410. There is a spaced distance G46 between the second side 332 of the third light-emitting unit 330 and the sidewall 411 of the groove 410, and there is a spaced distance G45 between the first side 331 of the third light-emitting unit 330 and one of the two sidewalls 412 of the groove 410 closer to the third light-emitting unit 330 (i.e., the sidewall 412 on the left of the groove 410). The first light-emitting unit 310 is separated from the two sidewalls 411 and the two sidewalls 412 of the groove 410. There is a spaced distance G42 between the second side 312 of the first light-emitting unit 310 and the sidewall 411 of the groove 410, and there is a spaced distance G41 between the first side 311 of the light-emitting unit 310 and one of the two sidewalls 412 of the groove 410 closer to the light-emitting unit 310 (i.e., the sidewall 412 on the right of the groove 410). The spaced distances G41, G42, G45 and G46 may be greater than or equal to 5 μm. However, the present disclosure is not limited thereto. The spaced distances G41, G42, G45 and G46 may independently be greater than or equal to 1 μm and less than or equal to 5 μm.

In FIG. 4, the spaced distances G41 and G45 are exemplarily the same, and the spaced distances G42 and G46 are exemplarily the same. However, the present disclosure is not limited thereto. The lengths of the spaced distances G41, G42, G45 and G46 may be independent from each other. That is, any two of the spaced distances G41, G42, G45 and G46 may be the same or different from each other. In addition, the spaced distances G46 on the upper and lower sides of the third light-emitting unit 330 may be equal to or unequal to each other, and the spaced distances G42 on the upper and lower sides of the first light-emitting unit 310 may be equal to or unequal to each other.

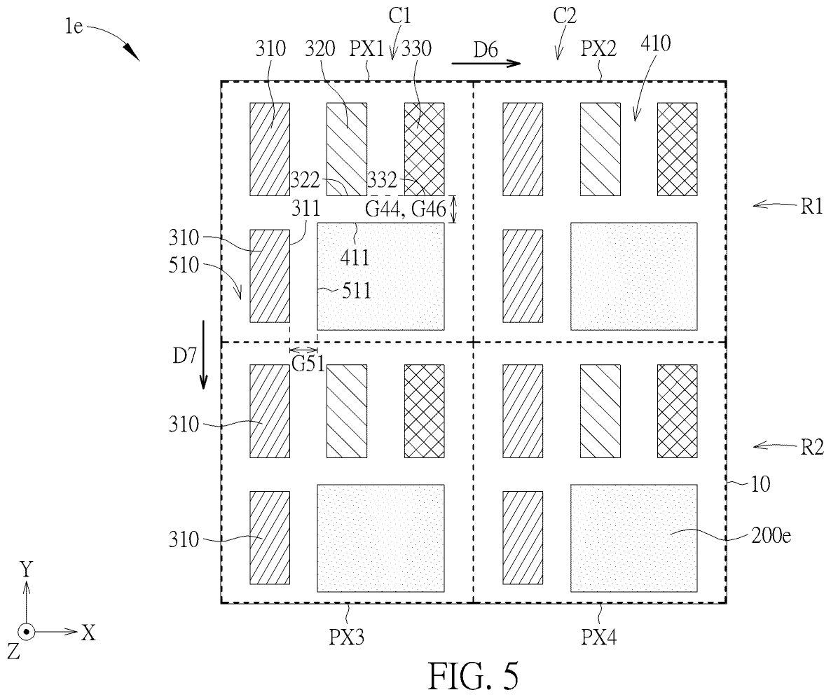

Please refer to FIG. 5, which is a schematic diagram showing a partial top view of an electronic device according to yet another embodiment of the present disclosure. The main difference between the electronic device 1e and the electronic device 1c is the configuration of the light emitting units and the grooves 510. In FIG. 5, the pixel defining layer 200e includes grooves 410 and grooves 510. The groove 410 extends along the direction D6 and spans at least two of the plurality of pixel regions PX1, PX2, PX3 and PX4. The groove 510 extends along the direction D7 and spans at least two of the plurality of pixel regions PX1, PX2, PX3 and PX4. The direction D6 is perpendicular to the direction D7. The electronic device 1e includes a plurality of light-emitting units (herein, the first light-emitting unit 310, the second light-emitting unit 320 and the third light-emitting unit 330 as an example) disposed in the groove 410 along the direction D6. The electronic device 1e may further include another light-emitting unit (herein, another first light-emitting unit 310 as an example). The another light-emitting unit and at least one of the plurality of light-emitting units (herein, the first light-emitting unit 310 as an example) in the groove 410 are arranged in the groove 510 along the direction D7. In other words, in the same pixel regions PX1, PX2, PX3 and PX4, the two light-emitting units disposed in the groove 510 are both the first light-emitting units 310 (herein, red light-emitting units). That is, the electronic device 1e includes a plurality of identical light-emitting units arranged in the groove 510 along the direction D7. In the embodiment, two red light-emitting units are disposed in the same pixel regions PX1, PX2, PX3 and PX4. It can also be regarded that the number of the red light-emitting units is greater than the number of the blue light-emitting unit and the number of the green light-emitting unit in the same pixel regions PX1, PX2, PX3 and PX4. Thereby, the problems such as color shift caused by the low luminous efficiency of the red light-emitting units (such as red LEDs) can be improved. In some embodiments, the plurality of the first light-emitting units 310 may also be green light-emitting units, blue light-emitting units or light-emitting units with other suitable colors, but not limited thereto.

In addition, the groove 510 has two sidewalls 511 parallel to the direction D7. In the same pixel regions PX1, PX2, PX3 and PX4, the first light-emitting unit 310 located at the lower portion is separated from at least one sidewall 511 of the groove 510. Herein, the first light-emitting unit 310 located at the lower portion is exemplarily separated from the two sidewalls 511 of the groove 510, and there is a spaced distance G51 between the first side 311 of the first light-emitting unit 310 located at the lower portion and the sidewall 511 of the groove 510. The spaced distance G51 may be greater than or equal to 5 μm. However, the present disclosure is not limited thereto. The spaced distance G51 may be greater than or equal to 1 μm and less than or equal to 5 μm. Furthermore, the spaced distances G51 on the left and right sides of the first light-emitting unit 310 may be equal or unequal with each other. For other details of the electronic device 1e, references may be made to the relevant descriptions of the electronic devices 1a, 1b, 1c and 1d mentioned above, and are not repeated herein.

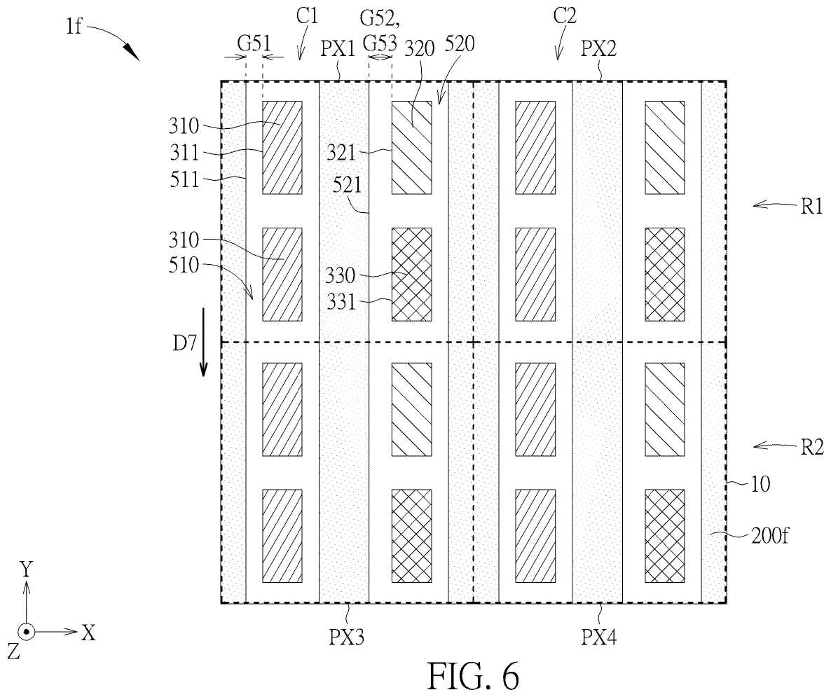

Please refer to FIG. 6, which is a schematic diagram showing a partial top view of an electronic device according to yet another embodiment of the present disclosure. The main difference between the electronic device if and the electronic device 1e in FIG. 5 is that the groove 410 extending along the direction D6 of the electronic device 1e is replaced by the groove 520 extending along the direction D7 in the electronic device 1f. In FIG. 6, the pixel defining layer 200f includes a groove 510 and a groove 520 extending along the direction D7 and spanning at least two of the plurality of pixel regions PX1, PX2, PX3 and PX4. That is, the groove 510 may be parallel to the groove 520. A plurality of first light-emitting units 310 may be arranged in the groove 510 along the direction D7, and a plurality of second light-emitting units 320 and a plurality of third light-emitting units 330 may be arranged alternately in the groove 520 along the direction D7. The direction D7 may be, for example, parallel to the direction Y. In the embodiment, the first light-emitting unit 310 is exemplary a red light-emitting unit, the second light-emitting unit 320 is exemplary a green light-emitting unit, and the third light-emitting unit 330 is exemplary a blue light-emitting unit. In other words, in the embodiment, a plurality of red light-emitting units are arranged in the groove 510 along the direction D7, and a plurality of green light-emitting units and a plurality of blue light-emitting units are arranged alternately in the groove 520 along the direction D7. In some embodiments, the plurality of first light-emitting units 310 may also be green light-emitting units, blue light-emitting units or light-emitting units with other suitable colors, but not limited thereto.

Furthermore, the groove 520 has two sidewalls 521 parallel to the direction D7. The second light-emitting unit 320 and the third light-emitting unit 330 are separated from at least one sidewall 521 of the groove 520. Herein, the second light-emitting unit 320 and the third light-emitting unit 330 are exemplarily separated from the two sidewalls 521 of the groove 520. There is a spaced distance G52 between the first side 321 of the second light-emitting unit 320 and the sidewall 521 of the groove 520. There is a spaced distance G53 between the first side 331 of the third light-emitting unit 330 and the sidewall 521 of the groove 520, and the spaced distance G53 may be greater than or equal to 5 μm. However, the present disclosure is not limited thereto. The spaced distances G51 and G53 may be greater than or equal to 1 μm and less than or equal to 5 μm. Furthermore, the spaced distances G52 on the left and right sides of the second light-emitting unit 320 may be equal or unequal, and the spaced distances G53 on the left and right sides of the third light-emitting unit 330 may be equal or unequal. For other details of the electronic device 1f, references may be made to the relevant descriptions of the electronic devices 1a, 1b, 1c, 1d and 1e mentioned above, and are not repeated herein.

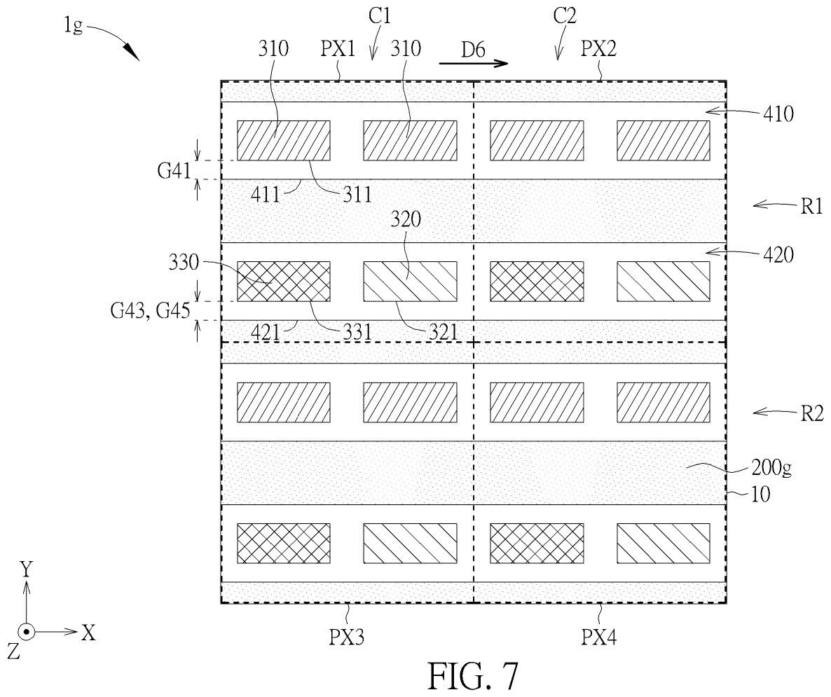

Please refer to FIG. 7, which is a schematic diagram showing a partial top view of an electronic device according to yet another embodiment of the present disclosure. The main difference between the electronic device 1g and the electronic device if in FIG. 6 is that the grooves 510 and 520 extending along the direction D7 in the electronic device if are respectively replaced by the grooves 410 and 420 extending along the direction D6 in the electronic device 1g. For example, the direction D6 may be parallel to the direction X, and the direction D7 may be parallel to the direction Y. In FIG. 7, the pixel defining layer 200g includes the grooves 410 and 420 extending along the direction D6 and spanning at least two of the plurality of pixel regions PX1, PX2, PX3 and PX4. That is, the groove 410 and the groove 420 may be parallel to each other. A plurality of first light-emitting units 310 are disposed in the groove 410 along the direction D6, and a plurality of third light-emitting units 330 and a plurality of second light-emitting units 320 are disposed alternately in the groove 420 along the direction D6. In the embodiment, the first light-emitting unit 310 is exemplary a red light-emitting unit, the second light-emitting unit 320 is exemplary a green light-emitting unit, and the third light-emitting unit 330 is exemplary a blue light-emitting unit. In other words, a plurality of red light-emitting units are arranged in the groove 410 along the direction D6, and a plurality of green light-emitting units and a plurality of blue light-emitting units are arranged alternately in the groove 420 along the direction D6. The groove 410 has two sidewalls 411 parallel to the direction D6, and there is a spaced distance G41 between the first side 311 of the first light-emitting unit 310 and the sidewall 411 of the groove 410. The groove 420 has two sidewalls 421 parallel to the direction D6, there is a spaced distance G43 between the first side 321 of the second light-emitting unit 320 and the sidewall 421 of the groove 420, and there is a spaced distance G45 between the first side 331 of the third light-emitting unit 330 and the sidewall 421 of the groove 420. The spaced distances G41, G43 and G45 may be greater than or equal to 5 μm. For other details of the electronic device 1g, references may be made to the relevant description of the electronic devices 1a, 1b, 1c, 1d, le and if mentioned above, and are not repeated herein. In some embodiments, the plurality of first light-emitting units 310 may also be green light-emitting units, blue light-emitting units or light-emitting units with other suitable colors, but not limited thereto.

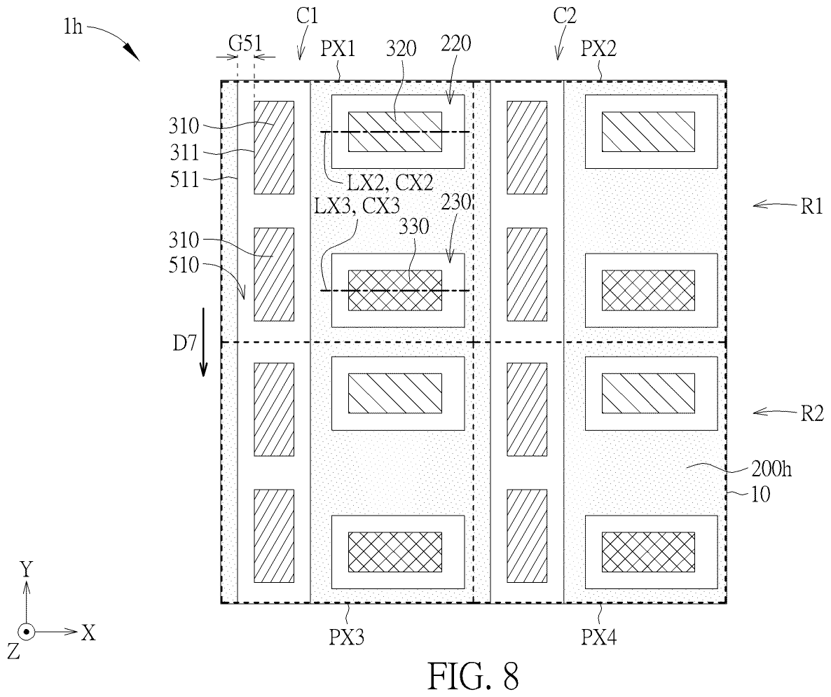

Please refer to FIG. 8, which is a schematic diagram showing a partial top view of an electronic device according to yet another embodiment of the present disclosure. The main difference between the electronic device 1h and the electronic device if in FIG. 6 is that the groove 520 extending along the direction D6 in the electronic device if is replaced by the second opening 220 and the third opening 230 in the electronic device 1h. In FIG. 8, the pixel defining layer 200h includes the groove 510 extending along the direction D7 and spanning at least two of the plurality of pixel regions PX1, PX2, PX3 and PX4, and includes the second opening 220 and the third opening 230 disposed alternately along the directions D7. For example, the direction D7 may be parallel to the direction Y. Furthermore, the same pixel regions PX1, PX2, PX3 and PX4 include a second opening 220 and a third opening 230. The second long axis LX2 of the second opening 220 is perpendicular to the direction D7, and the third long axis LX3 of the third opening 230 is perpendicular to the direction D7. That is, the second long axis LX2 is parallel to the third long axis LX3.

A plurality of first light-emitting units 310 are arranged in the groove 510 along the direction D7, the second light-emitting unit 320 is disposed in the second opening 220, and the third light-emitting unit 330 is disposed in the third opening 230. In the embodiment, the first light-emitting unit 310 is exemplary a red light-emitting unit, the second light-emitting unit 320 is exemplary a green light-emitting unit, and the third light-emitting unit 330 is exemplary a blue light-emitting unit. In other words, in the embodiment, a plurality of red light-emitting units are arranged in the groove 510 along the direction D7. Regarding the arrangement relationship between the second light-emitting unit 320 and the second opening 220 and the arrangement relationship between the third light-emitting unit 330 and the third opening 230, references may be made to the relevant description of the electronic device 1b in FIG. 2. For other details of the electronic device 1g, references may be made to the relevant description of the electronic devices 1a, 1b, 1c, 1d, le and if mentioned above, and are not repeated herein. In some embodiments, the plurality of first light-emitting units 310 may also be green light-emitting units, blue light-emitting units or light-emitting units with other suitable colors, but not limited thereto.

Please refer to FIG. 9, which is a schematic diagram showing a partial cross-sectional view of an electronic device according to yet another embodiment of the present disclosure. In FIG. 9, the electronic device 1i may include a substrate 10, a driving element 11, an insulating layer 12, a pixel defining layer 200, an underfill layer 13, a light-emitting unit 300, an optical clear resin 15, a photo spacer 14, a color filter layer 16, a light-shielding layer 17 and an opposite substrate 18, but not limited thereto.

Herein, the substrate 10 is exemplary a driving substrate, and a driving element 11 is formed thereon. The driving element 11 is, for example, a thin-film transistor (TFT) formed by a thin film process or a metal-oxide-semiconductor field-effect transistor (MOSFET) formed by a semiconductor process. The insulating layer 12 is disposed on the substrate 10 and the driving element 11. The pixel defining layer 200 is disposed on the insulating layer 12. An opening HH is formed in the pixel defining layer 200. The underfill layer 13 is disposed in the opening HH. The light-emitting unit 300 is disposed in the opening HH, and a portion of the light-emitting unit 300 is buried in the underfill layer 13.

The pixel defining layer 200 may be the aforementioned pixel defining layer 200a, 200b, 200c, 200d, 200e, 200f, 200g or 200h. Therefore, the opening HH may correspond to one of the first opening 210, the second opening 220, the third opening 230, the fourth opening 240, the groove 410, the groove 420, the groove 510 and the groove 520 mentioned above, and the light-emitting unit 300 may correspond to one of the first light-emitting unit 310, the second light-emitting unit 320, the third light-emitting unit 330 and the fourth light-emitting unit 340 mentioned above. For the sake of explanation convenience, the opening HH is exemplary the first opening 210, the light-emitting unit 300 is exemplary the first light-emitting unit 310, and the first light-emitting unit 310 is exemplary a red light-emitting unit.

A plurality of through holes (not shown) may be formed in the insulating layer 12, so that the conductive structure 313 of the first light-emitting unit 310 may be electrically connected with the driving element 11 through the through holes, and the driving element 11 may be served as the switch element of the first light-emitting unit 310. Herein, the driving element 11 and the first light-emitting unit 310 are electrically connected in a one-to-one manner, but not limited thereto. The number of the driving element 11 and the number of the light-emitting unit 300 corresponding to the driving element 11 may be adjusted according to actual needs. The material of the insulating layer 12 may include, for example, an organic material, other suitable materials, or a combination thereof. For example, the material of the insulating layer 12 may include, acrylic, epoxy or resin, but not limited thereto.

The material of the underfill layer 13 may include acrylic, epoxy, resin, a photoresist material, other suitable materials, or a combination of thereof, but not limited thereto. The underfill layer 13 can protect the pins of the light-emitting unit 300, so as to prevent the pins from falling off or having poor electrical connections due to external force. The material of the photo spacer 14 may include resin, an acrylic material, a photoresist material, other suitable materials, or a combination thereof, but not limited thereto. The photo spacer 14 can ensure the evenness of the height of the optical clear resin 15 to avoid optical mura such as uneven brightness caused by uneven height.

The material of the conductive structure 313 may include, for example, a metal material. The metal material may include, for example, aluminum, molybdenum, copper, titanium, other suitable materials, or a combination thereof, but not limited thereto. The underfill layer 13 is disposed in the first opening 210 and between the insulating layer 12 and the first light-emitting unit 310. The bottom (including the conductive structure 313) of the first light-emitting unit 310 is buried in the underfill layer 13. The underfill layer 13 can be configured to fix the first light-emitting unit 310 to reduce the probability of the peeling of the first light-emitting unit 310, and can be used to block moisture and/or oxygen from the outside, thereby reducing the possibility of the damage of the conductive structure 313 or the interior of the first light-emitting unit 310 caused by moisture and/or oxygen.

The optical clear resin 15 is disposed above the pixel defining layer 200, the underfill layer 13 and the first light-emitting unit 310, and may be filled in the first opening 210. The optical clear resin 15 may be used as an adhesive layer, an encapsulating layer or a filling layer. The optical clear resin 15 may combine the substrate 10 and the opposite substrate 18 and may be disposed on the first light-emitting unit 310, so that the substrate 10 and the opposite substrate 18 may be connected tightly without any gaps or air layers therebetween. Accordingly, the light of the first light-emitting unit 310 may penetrates the glass surface more smoothly and may not affect by external light and other light sources to generate light scattering and ghost image. The material of the optical clear resin 15 may include, for example, a transparent material, such as transparent resin, silicone, other suitable materials, or a combination thereof.

The color filter layer 16 and the light-shielding layer 17 are disposed on the opposite substrate 18. The light-shielding layer 17 is, for example, a black matrix, and may include at least one opening 17a. At least one portion of the color filter layer 16 overlaps the opening 17a of the light-shielding layer 17 to adjust the color of the light passing through the opening 17a. For example, the color of the color filter layer 16 may correspond to the light color of the first light-emitting unit 310. For example, the first light-emitting unit 310 is exemplary a red light-emitting unit, and the color filter layer 16 may be a red photoresist layer. When the light-emitting unit 300 is a green light-emitting unit or a blue light-emitting unit, the color filter layer 16 may be a green photoresist layer or a blue photoresist layer correspondingly.

The photo spacer 14 may be disposed on the opposite substrate 18, for example, may be disposed on the light-shielding layer 17 of the opposite substrate 18. One end of the photo spacer 14 is in contact with the light-shielding layer 17, and the other end of the photo spacer 14 is in contact with the pixel defining layer 200. The photo spacer 14 may be served to form a cell gap between the substrate 10 and the opposite substrate 18, and the cell gap may be configured to accommodate other elements of the electronic device 1i. The material of the photo spacer 14 may include a photoresist material, other suitable materials, or a combination thereof, but not limited thereto.

In some embodiments, at least a portion of the layers and/or elements on the opposite substrate 18 may be disposed on the substrate 10, but not limited thereto. For details of the opposite substrate 18, references may be made to the relevant description of the substrate 10 mentioned above, and are not repeated herein. The structure of the electronic device 1i is not limited to the above structure. The type, number and layout of the film layers and elements may be adjusted according to actual needs, and the electronic device 1i may selectively include other active elements, passive elements, circuits or other suitable circuit elements.

In the electronic device 1i, the pixel defining layer 200 is disposed at both sides of the light-emitting unit 300 and may be served as the blocking wall of the underfill layer 13, which may reduce the probability of losing the underfill layer 13 before the underfill layer 13 is cured, and may improve the fixation to the light-emitting unit 300, so as to reduce the probability of the peeling of the light-emitting unit 300. On the other hand, compared with the electronic device without the pixel defining layer 200, the electronic device without the pixel defining layer 200 needs to abut the photo spacer 14 by the light-emitting unit 300, the light-emitting unit 300 may be crushed by the photo spacer 14 and damaged. In the present disclosure, the pixel defining layer 200 can provide the position for abutting the photo spacer 14. Thereby, the probability of the light-emitting unit 300 being crushed and damaged may be reduced. Therefore, in the present disclosure, the yield of the electronic device 1i may be significantly enhanced by the pixel defining layer 200.

According to the present disclosure, with the configuration of the light-emitting units, it is favorable for the electronic device being applied as a high-resolution electronic device, and may provide the space for disposing the pixel defining layer. With the pixel defining layer, the probability of peeling of the light-emitting unit or the probability of the light-emitting unit being crushed and damaged by the photo spacer may be reduced, so as to enhance the yield of the electronic device. Furthermore, in the present disclosure, two red light-emitting units may be disposed in the same pixel region, or the number of the red light-emitting units is greater than the number of blue light-emitting units and the number of green light-emitting units in the same pixel region. Thereby, the problems such as color shift caused by the low luminous efficiency of the red light-emitting units can be improved. When the material of the pixel defining layer includes a reflective material, the brightness of the electronic device can be further improved. In some embodiments, the shape of each of the light-emitting units and/or openings in each of the pixel regions may also be a circle. In this way, each of the aforementioned central points may be at the center of the circle, and each of the central long axes and each of the long axes may be at the diameter of the circle.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a substrate;
a pixel defining layer disposed on the substrate, wherein the pixel defining layer comprises a first opening, a second opening and a third opening, the first opening, the second opening and the third opening respectively have a first long axis, a second long axis and a third long axis, the first opening and the second opening are arranged along a first direction, the first opening and the third opening are arranged along a second direction, and the first direction is different from the second direction; and
at least three light-emitting units respectively disposed in the first opening, the second opening and the third opening;
wherein an included angle between an extending direction of the first long axis and the first direction is greater than 45 degrees, an included angle between the extending direction of the first long axis and the second direction is less than 45 degrees, and an included angle between an extending direction of the third long axis and the second direction is greater than 45 degrees.

2. The electronic device of claim 1, wherein the at least three light-emitting units are respectively separated from at least one sidewall of the first opening, at least one sidewall of the second opening and at least one sidewall of the third opening.

3. The electronic device of claim 2, wherein there are spaced distances respectively between the at least three light-emitting units and the at least one sidewall of the first opening, the at least one sidewall of the second opening and the at least one sidewall of the third opening, and the spaced distances are greater than or equal to 5 μm.

4. The electronic device of claim 1, wherein one of the at least three light-emitting units disposed in the first opening is a red light-emitting unit, one of the at least three light-emitting units disposed in the second opening is a green light-emitting unit, and one of the at least three light-emitting units disposed in the third opening is a blue light-emitting unit.

5. The electronic device of claim 1, wherein the pixel defining layer further comprises a fourth opening, the electronic device further comprises another light-emitting unit disposed in the fourth opening, and the third opening and the fourth opening are arranged along the first direction.

6. The electronic device of claim 5, wherein the another light-emitting unit disposed in the fourth opening is a red light-emitting unit.

7. The electronic device of claim 1, wherein a material of the pixel defining layer comprises a reflective material.

8. An electronic device, comprising:
a substrate comprising a plurality of pixel regions arranged in an array;
a pixel defining layer disposed on the substrate, wherein the pixel defining layer comprises a first groove extending along a first direction and spanning at least two of the plurality of pixel regions; and
a plurality of light-emitting units arranged in the first groove along the first direction, wherein the plurality of light-emitting units are separated from at least one sidewall of the first groove.

9. The electronic device of claim 8, wherein there is a spaced distance between each of the plurality of light-emitting units and the at least one sidewall of the first groove, and the spaced distance is greater than or equal to 5 μm.

10. The electronic device of claim 8, wherein a material of the pixel defining layer comprises a reflective material.

11. The electronic device of claim 8, wherein each of the plurality of light-emitting units has a central long axis, and the central long axis is perpendicular to the first direction.

12. The electronic device of claim 8, wherein the plurality of light-emitting units comprises red light-emitting units, green light-emitting units and blue light-emitting units arranged alternately.

13. The electronic device of claim 8, wherein the pixel defining layer further comprises a second groove extending along a second direction and spanning at least two of the plurality of pixel regions, and the first direction is perpendicular to the second direction.

14. The electronic device of claim 13, further comprising:
another light-emitting unit, wherein the another light-emitting unit and at least one of the plurality of light-emitting units are arranged in the second groove along the second direction.

15. The electronic device of claim 14, wherein the another light-emitting unit and the at least one of the plurality of light-emitting units are red light-emitting units.

16. The electronic device of claim 8, wherein the pixel defining layer further comprises a first opening, and the first opening has a first long axis perpendicular to the first direction.

17. The electronic device of claim 16, wherein the first opening is staggered with the first groove along the first direction.

18. The electronic device of claim 16, wherein the pixel defining layer further comprises a second opening, and the second opening has a second long axis parallel to the first long axis.

19. The electronic device of claim 8, wherein the pixel defining layer further comprises a second groove extending along the first direction and spanning at least two of the plurality of pixel regions.

20. The electronic device of claim 19, further comprising:
a plurality of other light-emitting units disposed in the second groove along the first direction, wherein the plurality of light-emitting units disposed in the first groove are green light-emitting units and blue light-emitting units arranged alternately, and the plurality of other light-emitting units disposed in the second groove are all red light-emitting units.
